(19) United States
(12) Patent Application Publication
(10) Pub. No.: US 2024/0093368 A1
(43) Pub. Date: Mar. 21, 2024

(54) EDGE RING, SUBSTRATE PROCESSING APPARATUS INCLUDING THE SAME, AND SUBSTRATE PROCESSING METHOD USING THE SAME

(71) Applicant: SAMSUNG ELECTRONICS CO., LTD., Suwon-si (KR)

(72) Inventors: HONGTAEK LIM, Suwon-si (KR); HAKJUNG KIM, Suwon-si (KR); HONGSIK PARK, Suwon-si (KR); DONGGI LEE, Suwon-si (KR)

(73) Assignee: SAMSUNG ELECTRONICS CO., LTD., Suwon-si (KR)

(21) Appl. No.: 18/136,070

(22) Filed: Apr. 18, 2023

(30) Foreign Application Priority Data
Sep. 15, 2022 (KR) 10-2022-0115973

(51) Int. Cl. C23C 16/458; C23C 16/44; C23C 16/455; H01L 21/285; H01L 21/687

(52) U.S. Cl. CPC C23C 16/4585; C23C 16/4408; C23C 16/45565; H01L 21/28568; H01L 21/68721

(57) ABSTRACT

An edge ring includes a ring body having an axis parallel to a first direction; and a plurality of protrusions provided at an inner side surface of the ring body and protruding toward the axis, the plurality of protrusions being spaced apart from each other in a circumference direction of the edge ring, wherein a first distance between the axis and a first point on the inner side surface of the ring body between two adjacent protrusions of the plurality of protrusions is larger than a second distance between the axis and a second point on the inner side surface of the ring body at which a protrusion of the plurality of protrusions is provided.

### CROSS-REFERENCE TO RELATED APPLICATION

This application is based on and claims priority under 35 U.S.C. § 119 to Korean Patent Application No. 10-2022-0115973, filed on Sep. 15, 2022, in the Korean Intellectual Property Office, the disclosure of which is incorporated by reference herein in its entirety.

### BACKGROUND

The present disclosure relates to an edge ring, a substrate processing apparatus including the same, and a substrate processing method using the same, and in particular, to an edge ring configured to allow for a uniform supply of a purge gas, a substrate processing apparatus including the same, and a substrate processing method using the same.

A semiconductor device may be fabricated through various processes. For example, the semiconductor device may be fabricated by performing a photolithography process, an etching process, and a deposition process on a silicon wafer. Various deposition systems may be used for the deposition process. For example, a deposition system may be configured to perform the deposition process on a single wafer. An edge ring enclosing the substrate may be used in such a system. In addition, the deposition system may be configured to supply a purge gas to a region on a wafer during the deposition process. However, in related art methods, the purge gas may not be properly ejected.

### SUMMARY

Example embodiments an edge ring, which may be configured to uniformly supply a purge gas in a deposition process, a substrate processing apparatus including the same, and a substrate processing method using the same.

Further, example embodiments provide an edge ring, which may be configured to precisely dispose a substrate at a desired position, a substrate processing apparatus including the same, and a substrate processing method using the same.

Further, example embodiments provide an edge ring, which may be configured to control a thickness of a deposition layer, a substrate processing apparatus including the same, and a substrate processing method using the same.

Additional aspects will be set forth in part in the description which follows and, in part, will be apparent from the description, or may be learned by practice of the presented embodiments.

According to an aspect of an example embodiment, an edge ring includes: a ring body having an axis parallel to a first direction; and a plurality of protrusions provided at an inner side surface of the ring body and protruding toward the axis, the plurality of protrusions being spaced apart from each other in a circumference direction of the edge ring, wherein a first distance between the axis and a first point on the inner side surface of the ring body between two adjacent protrusions of the plurality of protrusions is larger than a second distance between the axis and a second point on the inner side surface of the ring body at which a protrusion of the plurality of protrusions is provided.

According to an aspect of an example embodiment, a substrate processing apparatus includes: a stage configured to support a substrate; and an edge ring provided on the stage, wherein the edge ring includes: a ring body having an axis parallel to a first direction; and a plurality of protrusions provided at an inner side surface of the ring body and protruding inward from the ring body, the plurality of protrusions being spaced apart from each other in a circumference direction of the edge ring.

According to an aspect of an example embodiment, a substrate processing method includes: placing a substrate in a substrate processing apparatus; supplying a process gas into the substrate processing apparatus; and supplying a purge gas to a region on the substrate, wherein the substrate processing apparatus includes a stage configured to support the substrate, and an edge ring provided on the stage, wherein the edge ring includes a ring body having an axis parallel to a first direction, and a plurality of protrusions provided at an inner side surface of the ring body and protruding toward the axis, and the plurality of protrusions are spaced apart from each other in a circumference direction of the edge ring, wherein the stage includes a purge hole formed below the edge ring and exposed by a top surface of the stage, and wherein the supplying of the purge gas to the region on the substrate includes supplying the purge gas through the purge hole.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a sectional view illustrating a substrate processing apparatus according to an embodiment of the disclosure;

FIG. 2 is a sectional view illustrating a portion ‘X’ of FIG. 1 according to an embodiment of the disclosure.

FIG. 3 is an exploded sectional view of the portion ‘X’ of FIG. 2 according to an embodiment of the disclosure;

FIG. 4 is a diagram illustrating an edge ring according to an embodiment of the disclosure;

FIG. 5 is a diagram of a portion ‘Y’ of FIG. 4 according to an embodiment of the disclosure;

FIG. 6 is a diagram illustrating a stage according to an embodiment of the disclosure;

FIG. 7 is a flowchart illustrating a substrate processing method according to an embodiment of the disclosure;

FIGS. 8, 9, 10, 11 and 12 are diagrams sequentially illustrating the substrate processing method according to the flowchart of FIG. 7 according to an embodiment of the disclosure;

FIGS. 13 and 14 are diagrams illustrating an edge ring according to an embodiment of the disclosure; and

FIG. 15 is a diagram of a portion ‘Z’ of FIG. 14 according to an embodiment of the disclosure.

### DETAILED DESCRIPTION

Example embodiments of the disclosures will now be described more fully with reference to the accompanying drawings, in which example embodiments are shown. Like reference numerals in the drawings denote like elements, and thus their description will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

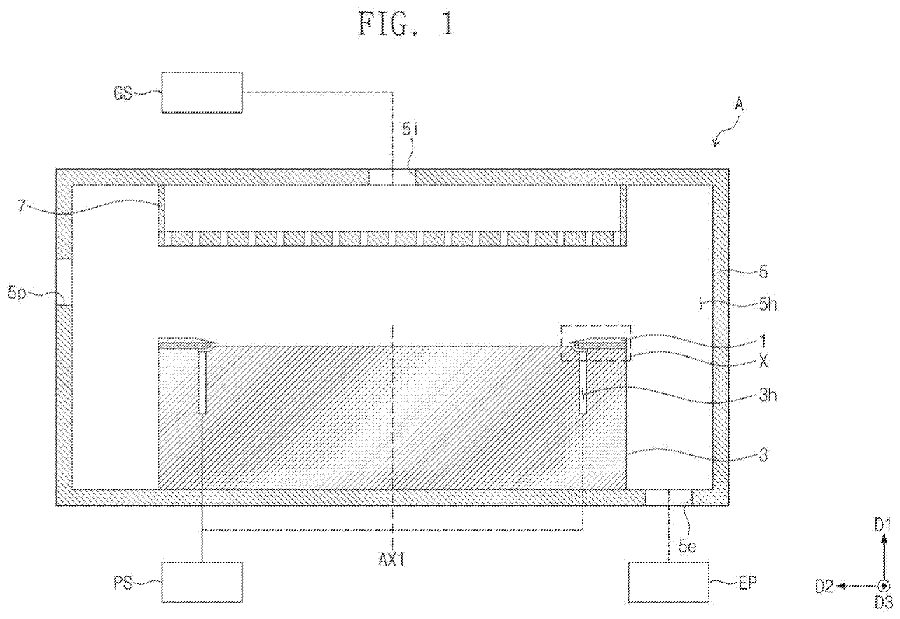

FIG. 1 is a sectional view illustrating a substrate processing apparatus according to an embodiment of the inventive concept.

Herein, the reference numbers D1, D2, and D3 may be used to denote a first direction, a second direction, and a third direction, respectively, which may not be parallel to each other. The first direction D1 may be referred to as a vertical direction, and each of the second and third directions D2 and D3 may be referred to as a horizontal direction.

Referring to FIG. 1, a substrate processing apparatus A may be provided. The substrate processing apparatus A may be an apparatus, which is configured to form a deposition layer on a substrate. For example, the substrate processing apparatus A may be configured to perform an atomic layer deposition (ALD) and/or chemical vapor deposition (CVD) process. The term ‘substrate’ may refer to a silicon wafer, but the disclosure is not limited to this example. The substrate processing apparatus A may include a process chamber 5, a stage 3, an edge ring 1, a shower head 7, a process gas supplier GS, a purge gas supplier PS, and an exhausting portion EP.

The process chamber 5 may be provided to have a process space 5h. The process space 5h may be used to perform a deposition process on a substrate. During the deposition process, the process space 5h may be in a substantially vacuum state, but the disclosure is not limited to this example. The stage 3, the edge ring 1, the shower head 7, and so forth may be disposed in the process space 5h. A substrate loading hole 5p, a gas injection hole 5i, and a gas exhaust hole 5e may be formed in the process chamber 5. The substrate loading hole 5p may be used to insert or unload the substrate into or from the process space 5h. The gas injection hole 5i may be connected to the process gas supplier GS. A process gas, which is supplied from the process gas supplier GS, may be supplied into the process space 5h through the gas injection hole 5i. A gas exhaust hole 5e may be connected to the exhausting portion EP. A fluidic material in the process space 5h may be exhausted to the exhausting portion EP through the gas exhaust hole 5e.

The stage 3 may support the substrate. The stage 3 may be configured to fasten the substrate. For example, the stage 3 may be configured to fasten the substrate to a specific position on the stage 3 using a vacuum pressure and/or an electrostatic force. To fasten the substrate, the stage 3 may include a vacuum chuck, an electrostatic chuck (ESC), and so forth. The stage 3 may also be configured to control a temperature of the substrate. For example, the stage 3 may be used to heat or cool the substrate. To do this, the stage 3 may include a heating line and/or a cooling conduit. When viewed in a plan view, the stage 3 may have a circular shape. A purge hole 3h may be provided in the stage 3. The purge hole 3h may be connected to the purge gas supplier PS. A purge gas, which is supplied from the purge gas supplier PS, may be ejected to a region on a top surface of the stage 3 through the purge hole 3h.

The edge ring 1 may be disposed on the stage 3. For example, the edge ring 1 may be loaded on the stage 3 in a detachable manner. When viewed in a plan view, the edge ring 1 may be provided to enclose the substrate loaded on the stage 3. The edge ring 1 may have an axis AX1 that is parallel to the first direction D1. The edge ring 1 may be disposed on the purge hole 3h.

The shower head 7 may be spaced apart from the stage 3 in an upward direction. The shower head 7 may be provided below the gas injection hole 5i. The process gas, which is supplied through the gas injection hole 5i, may be distributed by the shower head 7 and then may be supplied into the process space 5h.

The process gas supplier GS may be configured to supply a process gas into the process chamber 5. For example, the process gas supplier GS may supply a tungsten hexafluoride (WF₆) gas into the process space 5h. The process gas supplier GS may include a process gas tank, a compressor, a conduit, a valve, and so forth for supplying gas into the process space 5h.

The purge gas supplier PS may be configured to supply a purge gas into the process chamber 5. The purge gas may contain an inactive or inert gas (e.g., nitrogen (N 2) or argon (Ar) gas) and but embodiments of the disclosure are not limited to this example. The purge gas supplier PS may be connected to the purge hole 3h. The purge gas supplier PS may supply the purge gas to a region on the stage 3 through the purge hole 3h. The purge gas supplier PS may include a purge gas tank, a compressor, a conduit, a valve, and so forth for supplying the purge gas to a region on the stage 3 through the purge hole 3h.

The exhausting portion EP may be connected to the process space 5h through the gas exhaust hole 5e. The exhausting portion EP may be configured to exhaust a fluidic material from the process space 5h. The exhausting portion EP may include a vacuum pump or the like for exhausting the fluidic material from the process space 5h.

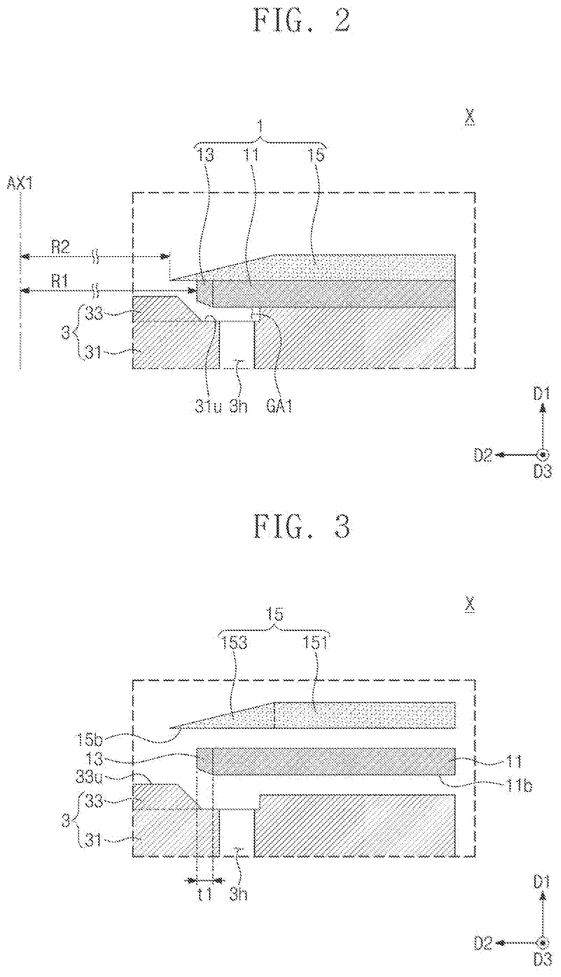

FIG. 2 is a sectional view illustrating a portion ‘X’ of FIG. 1 according to an embodiment of the disclosure. FIG. 3 is an exploded sectional view of the portion ‘X’ of FIG. 2 according to an embodiment of the disclosure.

Referring to FIGS. 2 and 3, the stage 3 may include a stage body 31 and a plateau 33. The purge hole 3h may be provided in the stage body 31. The purge hole 3h may be connected to a space on the top surface of the stage 3. More specifically, the purge hole 3h may be provided to penetrate a top surface 31u of the stage body 31. The purge hole 3h may face a bottom surface 11b of the edge ring 1. The bottom surface 11b of the edge ring 1 may be spaced apart from the purge hole 3h in an upward direction. Accordingly, a gap GA1 may be formed between the purge hole 3h and the edge ring 1. The plateau 33 may be located on the stage body 31. A level of a top surface 33u of the plateau 33 may be higher than a level of the top surface 31u of the stage body 31. A substrate may be disposed on the plateau 33. The stage 3 may further include a heater. The heater may be placed in the stage body 31. The heater may be used to control a temperature of the substrate disposed on the stage 3.

The edge ring 1 may include a ring body 11, a protrusion 13, and an upper ring 15.

The axis AX1 may be chosen to pass through a center of the ring body 11. The ring body 11 may be disposed on the stage body 31. The ring body 11 may be fastened to the top surface 31u of the stage body 31. Alternatively, the ring body 11 may be mounted on the stage body 31 in a detachable manner. The ring body 11 may be formed of or include a ceramic-based material.

The protrusion 13 may be coupled to an inner side surface of the ring body 11. More specifically, the protrusion 13 may protrude from the inner side surface of the ring body 11 toward the axis AX1. Hereinafter, a distance between an inner side surface of the protrusion 13 and the axis AX1 may be referred to as a first radius R1. In an embodiment, the first radius R1 may be larger than about 150 mm A thickness of the protrusion 13 in a radial direction will be referred to as a first thickness t1. The first thickness t1 may range from about 0.15 mm to about 0.35 mm More specifically, the first thickness t1 may be about 0.25 mm. The protrusion 13 may be formed of or include a ceramic-based material. The protrusion 13 and the ring body 11 may be provided to form a single object. However, embodiments of the disclosure are not limited to this example, and the protrusion 13 may be coupled to the ring body 11 in a detachable manner.

The upper ring 15 may be placed on the ring body 11. A distance between the upper ring 15 and the axis AX1 may be referred to as a second radius R2. That is, an inner radius of the upper ring 15 may be referred to as the second radius R2. The second radius R2 may be smaller than the first radius R1. Thus, in an inner region of the ring body 11, a portion of a bottom surface 15b of the upper ring 15 may not be covered by the ring body 11. In an embodiment, the second radius R2 may be smaller than about 150 mm. The upper ring 15 may include an upper ring body 151 and an inner ring 153. The upper ring body 151 may be provided to have a uniform thickness and a substantially flat top surface. The inner ring 153 may be coupled to an inner side surface of the upper ring body 151. As a distance from the upper ring body 151 increases in an inward direction, a thickness of the inner ring 153 may decrease. The upper ring 15 may be formed of or include a ceramic-based material. The upper ring 15 may be mounted on the ring body 11 in a detachable manner. However, the disclosure is not limited to this example, and in an embodiment, the upper ring 15 and the ring body 11 may be provided to form a single object.

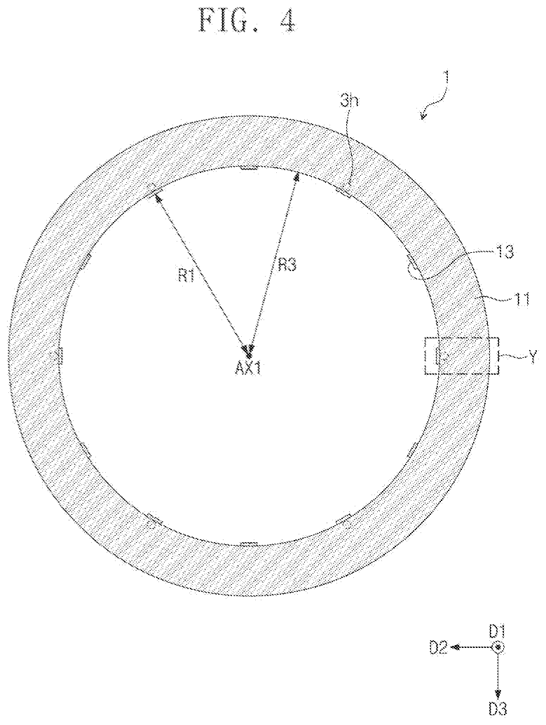

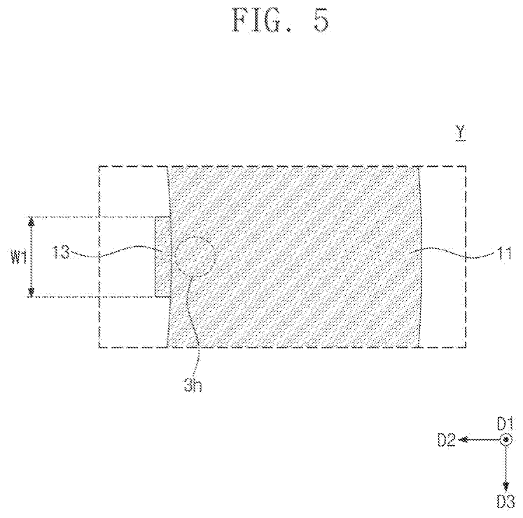

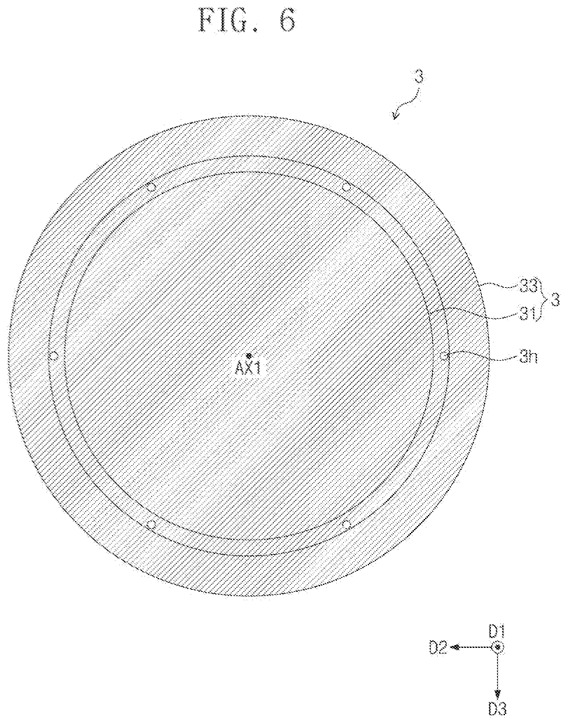

FIG. 4 is a diagram illustrating an edge ring according to an embodiment of the disclosure. FIG. 5 is a diagram of a portion ‘Y’ of FIG. 4 according to an embodiment of the disclosure. FIG. 6 is a diagram illustrating a stage according to an embodiment of the disclosure.

Referring to FIGS. 4 to 6, the purge hole 3h may overlap the ring body 11, when viewed in a plan view. In an embodiment, a plurality of purge holes 3h may be provided. For example, six purge holes 3h may be provided. However, the disclosure is not limited to this example. The purge holes 3h may be spaced apart from each other in a circumference direction. Reference to one of the purge holes 3h is made for convenience of description.

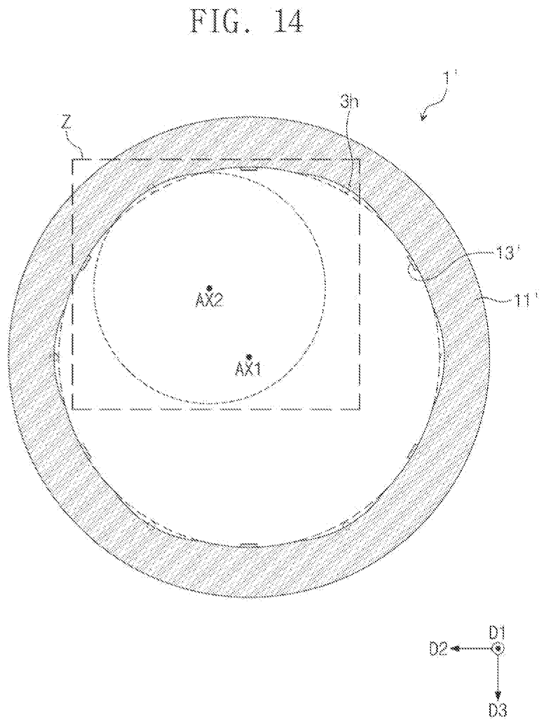

Referring to FIG. 4, a distance between the ring body 11 and the axis AX1 may be referred to as a third radius R3. In other words, an inner radius of the ring body 11 may be referred to as the third radius R3. For example, the third radius R3 may be larger than about 150 mm. The third radius R3 may be larger than each of the first and second radii R1 and R2. The third radius R3 may be uniform. In other words, the inner side surface of the ring body 11 may have the same shape as a side surface of a circular pillar. However, embodiments of the disclosure are not limited to this example. Further details are provided with reference to FIGS. 13 to 15.

In an embodiment, a plurality of protrusions 13 may be provided. For example, twelve protrusions may be provided, as shown in FIG. 4. The protrusions 13 may be spaced apart from each other in a circumference direction. Reference to one of the protrusions 13 is made for convenience of description.

Referring to FIG. 5, a width of the protrusion 13 in a circumference direction may be referred to as a first width w1. The first width w1 may range from about 1.0 mm to about 2.2 mm. More specifically, the first width w1 may be about 1.6 mm.

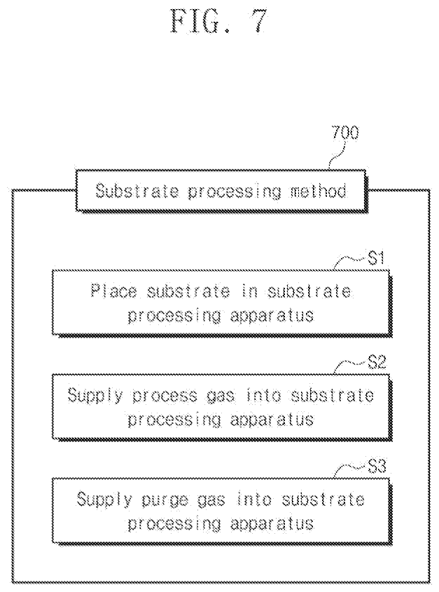

FIG. 7 is a flowchart illustrating a substrate processing method according to an embodiment of the disclosure.

Referring to FIG. 7, a substrate processing method 700 may be provided. The substrate processing method S may be a method of processing a substrate using the substrate processing apparatus A described with reference to FIGS. 1 to 6. The substrate processing method 700 may include placing the substrate in the substrate processing apparatus in operation S1, supplying a process gas into the substrate processing apparatus in operation S2, and supplying a purge gas into the substrate processing apparatus in operation S3.

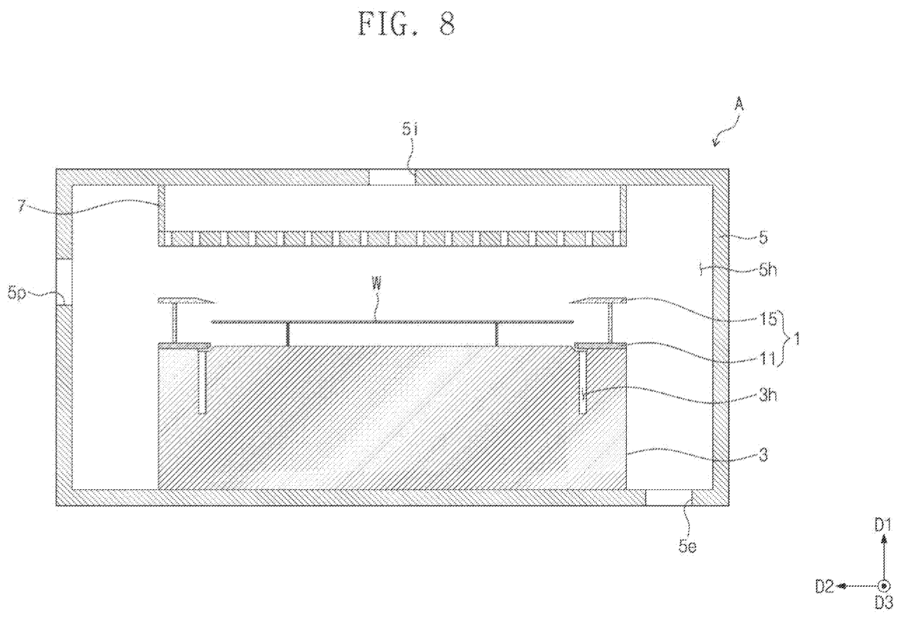

Hereinafter, the substrate processing method 700 of FIG. 7 will be described in more detail with reference to FIGS. 8 to 12.

FIGS. 8, 9, 10, 11 and 12 are diagrams sequentially illustrating the substrate processing method according to the flowchart of FIG. 7 according to an embodiment of the disclosure.

Referring to FIGS. 7, 8, and 9, the placing of the substrate in the substrate processing apparatus in operation S1 may include loading a substrate W on the stage 3. During this process, the upper ring 15 may be elevated in an upward direction by a supporting pin. In other words, the substrate W may be disposed on the stage 3, when the upper ring 15 is elevated from the stage 3 in the upward direction. After the placing of the substrate W, the upper ring 15 may be lowered.

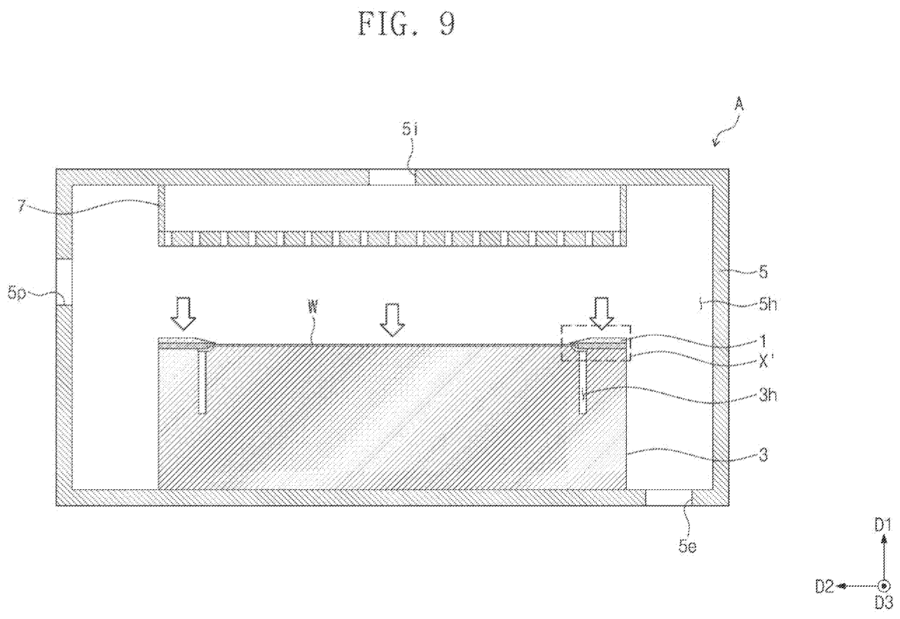

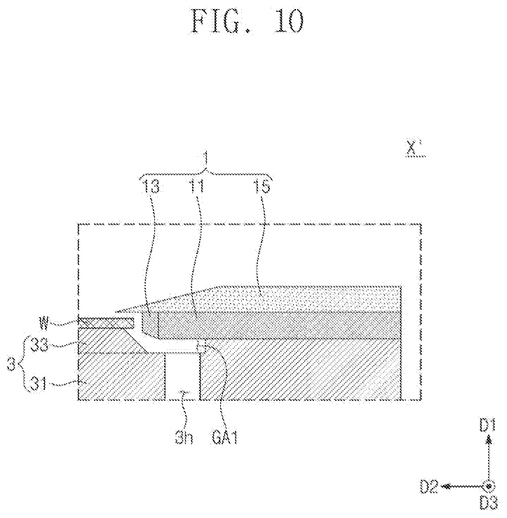

Referring to FIG. 10 showing the portion X′ of FIG. 9, the substrate W may be disposed on the plateau 33. An outer side surface of the substrate W may face an inner side surface of the protrusion 13. In an embodiment, the outer side surface of the substrate W may be spaced apart from the inner side surface of the protrusion 13. Thus, the gap GA1, which is formed on the purge hole 3h, may be connected to a space on the substrate W.

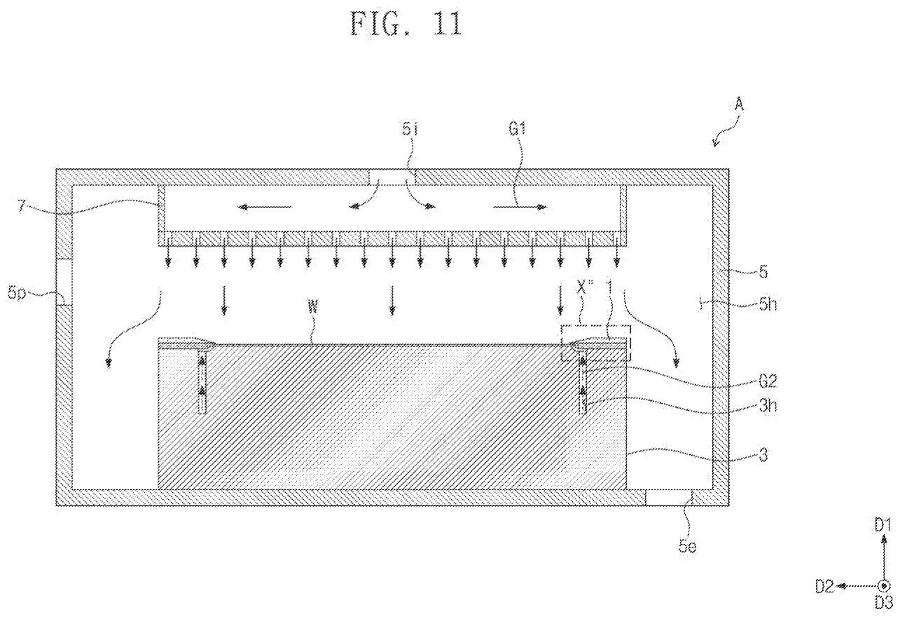

Referring to FIGS. 7 and 11, the supporting of the process gas into the substrate processing apparatus in operation S2 may include supplying a process gas G1 from the process gas supplier GS into the substrate processing apparatus. The process gas G1 may be supplied onto the substrate W in the process space 5h in a uniformly distributed manner by the shower head 7.

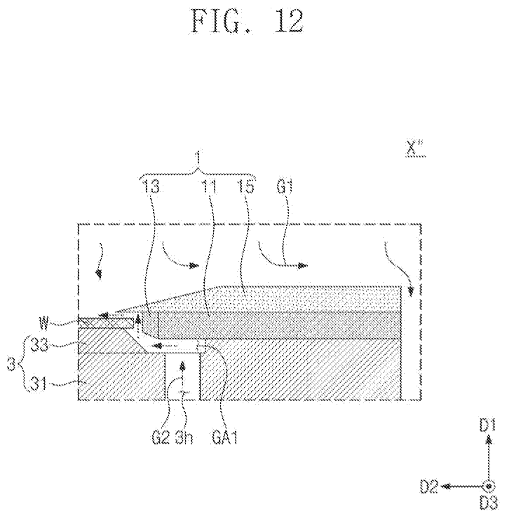

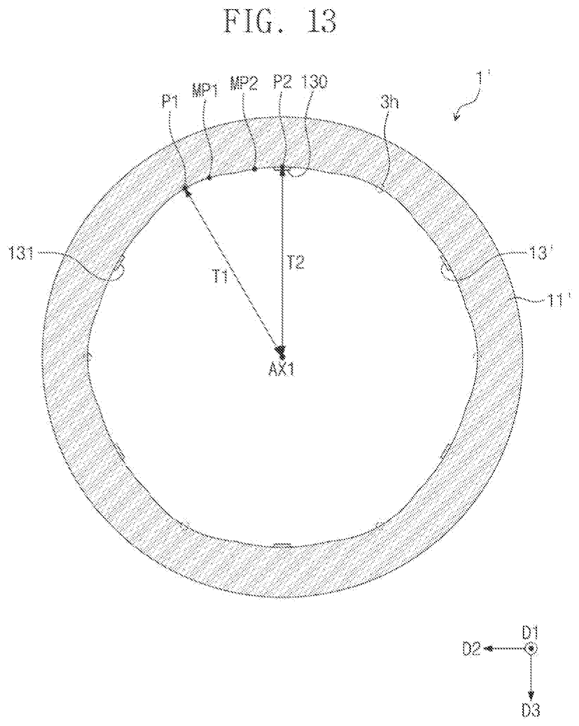

Referring to FIGS. 7, 11, and 12, where FIG. 12 shows portion X″ of FIG. 11, the supplying of the purge gas into the substrate processing apparatus in operation S3 may include supplying a purge gas G2 from the purge gas supplier PS into the substrate processing apparatus. The purge gas G2 may be delivered into the gap GA1 through the purge hole 3h. The purge gas G2, which is supplied into the gap GA1, may be moved to a region on the substrate W through a space between the substrate W and the protrusion 13. The process gas G1 and the purge gas G2 may be used to form a deposition layer on the substrate W.

In an edge ring according to an embodiment of the disclosure, a substrate processing apparatus including the same, and a substrate processing method using the same, a protrusion may be used in an operation of positioning or aligning a substrate. For example, a substrate, which is disposed in an inner region of a ring body, may be prevented from being placed at a position excessively offset from an axis of the ring body. Furthermore, the substrate may be precisely disposed at a desired position. Accordingly, a yield in the deposition process on the substrate may be increased. In addition, a thickness of a deposition layer, which is deposited on the substrate, may be controlled.

In an edge ring according to an embodiment of the disclosure, a substrate processing apparatus including the same, and a substrate processing method using the same, since a plurality of protrusions are disposed to be spaced apart from each other, a purge gas may be supplied to a region on a substrate through a space between the protrusions, even when the substrate is eccentrically placed. Accordingly, the purge gas to a region on the substrate may be uniformly supplied. As a result, a deposition process on the substrate may be effectively performed.

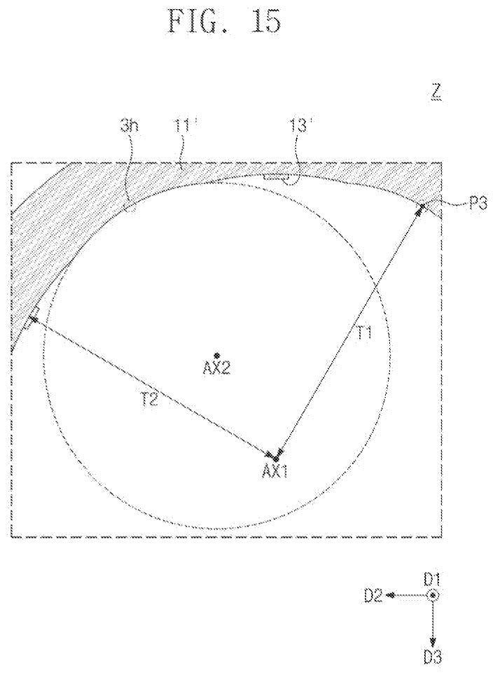

FIGS. 13 and 14 are diagrams illustrating an edge ring according to an embodiment of the disclosure. FIG. 15 is a diagram of a portion ‘Z’ of FIG. 14 according to an embodiment of the disclosure.

In the following description, elements previously described with reference to FIGS. 1 to 12 may be identified by the same reference number without repeating an overlapping description thereof.

Referring to FIGS. 13 to 15, a distance between a point of a ring body 11′, such as point P1, which is located between two adjacent protrusions 13′, such as protrusions 130 and 131, and the axis AX1 may be referred to as a first distance T1. For example, the first distance T1 may be a distance from a point P1 of the ring body 11′, which may be equidistant from two adjacent protrusions 13′, such as protrusions 130 and 131, to the axis AX1. Alternatively, the first distance T1 may be a distance between the ring body 11′ and the axis AX1, which is measured at a position overlapping the purge hole 3h in a plan view. That is, the point such as P1 may be positioned at the purge hole 3h. In an embodiment, the first distance T1 may be larger than about 150 mm.

A distance from a point of the ring body 11′ at which each of the protrusions 13′ is placed, such as point P2 where the protrusion 130 is positioned, to the axis AX1 may be referred to as a second distance T2. More specifically, the second distance T2 may be a distance between a point of the ring body 11′ corresponding to one of the protrusions 13′, and the axis AX1. The second distance T2 may be larger than about 150 mm.

In an embodiment, the first distance T1 may be different from the second distance T2. More specifically, the first distance T1 may be larger than the second distance T2. In other words, the third radius R3 (e.g., of FIG. 4) may not be uniform, unlike the embodiment described with reference to FIG. 4. This structure may be formed when using a ring body having a nonuniform thickness in a radial direction. However, embodiments of the disclosure are not limited to this example.

As a distance from a point, which is equidistant from two adjacent protrusions 13′, increases in a direction toward each of the protrusions 13′, the distance between the ring body 11′ and the axis AX1 may decrease accordingly. In other words, as a measurement point is changed in a circumference direction from the point P1, upon which the first distance T1 is based, to the point P2, upon which the second distance T2 is based, the distance between the ring body 11′ and the axis AX1 may decrease accordingly. For example, as a measurement point is changed from measurement point MP1, which is closer to P1 (P1 being equidistant from protrusions 130 and 131), to measurement point MP2, which is closer to P2 (P2 corresponding to where the protrusion 130 is placed), the first distance T1 continually decreases and approaches the value of the distance T2.

Referring to FIG. 15, in an embodiment, between two adjacent protrusions 13′, an inner side surface of the ring body 11′ may have a curved portion, which is centered at an eccentric axis AX2. For example, between the two adjacent protrusions 13′, a portion of the inner side surface of the ring body 11′ may be a portion of a side surface of a circular pillar, which is centered at the eccentric axis AX2. The eccentric axis AX2 may be spaced apart from the axis AX1 in an outward direction.

In an edge ring according to an embodiment of the disclosure, a substrate processing apparatus including the same, and a substrate processing method using the same, due to the nonuniform thickness of the ring body, a space for flow of the purge gas may be secured. More specifically, even when the substrate is eccentrically placed on the stage and is in partial contact with at least one of the protrusions, a space between the inner ring and the substrate at a position of the purge hole may be secured. Thus, the purge gas, which is transferred through the purge hole, may be effectively supplied to a space on the substrate through the space between the inner ring and the substrate. Accordingly, the purge gas may be uniformly supplied to a space on the substrate. That is, even when the substrate is misaligned, the deposition process may be effectively performed.

In an edge ring according to one or more embodiments of the disclosure, a substrate processing apparatus including the same, and a substrate processing method using the same, a purge gas during a deposition process may be uniformly supplied.

In an edge ring according to one or more embodiments of the disclosure, a substrate processing apparatus including the same, and a substrate processing method using the same, a substrate may be precisely placed at a desired position.

In an edge ring according to one or more embodiments of the disclosure, a substrate processing apparatus including the same, and a substrate processing method using the same, a thickness of a deposition layer may be precisely controlled.

While example embodiments of the disclosure have been particularly shown and described, it will be understood by one of ordinary skill in the art that variations in form and detail may be made therein without departing from the spirit and scope of the claims.

What is claimed is:

1. An edge ring comprising:
a ring body having an axis parallel to a first direction; and
a plurality of protrusions provided at an inner side surface of the ring body and protruding toward the axis, the plurality of protrusions being spaced apart from each other in a circumference direction of the edge ring,
wherein a first distance between the axis and a first point on the inner side surface of the ring body between two adjacent protrusions of the plurality of protrusions is larger than a second distance between the axis and a second point on the inner side surface of the ring body at which a protrusion of the plurality of protrusions is provided.

2. The edge ring of claim 1, wherein the ring body comprises a portion on the inner side surface of the ring body in which a third distance between the axis and a measurement point continuously decreases as the measurement point is changed from a third point which is equidistant from two adjacent protrusions of the plurality of protrusions, to a fourth point at which a protrusion of the plurality of protrusions is provided.

3. The edge ring of claim 1, wherein the ring body comprises a ceramic material.

4. The edge ring of claim 1, wherein number of the plurality of protrusions is 12.

5. The edge ring of claim 1, further comprising an upper ring on the ring body,
wherein a fourth distance between the upper ring and the axis is smaller than a fifth distance between each of the plurality of protrusions and the axis.

6. The edge ring of claim 5, wherein the upper ring comprises:
an upper ring body; and
an inner ring provided in an inner region of the upper ring body, and
wherein a height of the inner ring decreases in an inward direction.

7. The edge ring of claim 5, wherein, in an inner region of the ring body, a portion of a bottom surface of the upper ring is exposed.

8. The edge ring of claim 5, wherein the fourth distance between the upper ring and the axis is smaller than 150 mm, and
wherein each of the first distance and the second distance is larger than 150 mm.

9. A substrate processing apparatus comprising:
a stage configured to support a substrate; and
an edge ring provided on the stage,
wherein the edge ring comprises:
a ring body having an axis parallel to a first direction; and
a plurality of protrusions provided at an inner side surface of the ring body and protruding inward from the ring body, the plurality of protrusions being spaced apart from each other in a circumference direction of the edge ring.

10. The substrate processing apparatus of claim 9, wherein a number of the plurality of protrusions is 12.

11. The substrate processing apparatus of claim 9, wherein a first thickness of the ring body, in a radial direction of the ring body, in a first region between two adjacent protrusions of the plurality of protrusions is smaller than a second thickness of the ring body, in the radial direction of the ring body, in a second region where a protrusion of the plurality of protrusions is provided.

12. The substrate processing apparatus of claim 11, wherein, between two adjacent protrusions of the plurality of protrusions, the inner side surface of the ring body comprises a curved portion which centered at an eccentric axis, and
wherein the eccentric axis is spaced apart from the axis in an outward direction.

13. The substrate processing apparatus of claim 9, wherein the stage comprises a plurality of purge holes provided below the edge ring,
wherein each purge hole of the plurality of purge holes is exposed at a top surface of the stage, and
where the plurality of purge holes are spaced apart from each other in the circumference direction.

14. The substrate processing apparatus of claim 13, wherein a number of the plurality of purge holes is 6.

15. The substrate processing apparatus of claim 13, wherein the edge ring further comprises an upper ring on the ring body, and
wherein a first distance between the upper ring and the axis is smaller than a second distance between each protrusion of the plurality of protrusions and the axis such that a bottom surface of the upper ring is exposed in an inner region of the ring body.

16. The substrate processing apparatus of claim 13, wherein the ring body is spaced apart from the plurality of purge holes in an upward direction such that the plurality of purge holes, which is exposed by the top surface of the stage, faces a bottom surface of the ring body.

17. The substrate processing apparatus of claim 13, wherein the stage comprises:
a stage body, in which the plurality of purge holes is provided; and
a heater provided in the stage body.

18. The substrate processing apparatus of claim 9, further comprising a shower head spaced apart from the stage in an upward direction.

19. A substrate processing method comprising:
placing a substrate in a substrate processing apparatus;
supplying a process gas into the substrate processing apparatus; and
supplying a purge gas to a region on the substrate,
wherein the substrate processing apparatus comprises a stage configured to support the substrate, and an edge ring provided on the stage,
wherein the edge ring comprises a ring body having an axis parallel to a first direction, and a plurality of protrusions provided at an inner side surface of the ring body and protruding toward the axis, and the plurality of protrusions are spaced apart from each other in a circumference direction of the edge ring,
wherein the stage comprises a purge hole formed below the edge ring and exposed by a top surface of the stage, and
wherein the supplying of the purge gas to the region on the substrate comprises supplying the purge gas through the purge hole.

20. The substrate processing method of claim 19, wherein a first distance between the axis and a first point on the inner side surface of the ring body between two adjacent protrusions of the plurality of protrusions is larger than a second distance between the axis and a second point on the inner side surface of the ring body at which a protrusion of the plurality of protrusions is provided.
